(19) United States
(12) Patent Application Publication
(10) Pub. No.: US 2011/0058410 A1
(43) Pub. Date: Mar. 10, 2011

(54) SEMICONDUCTOR MEMORY DEVICE

(75) Inventor: Taro OSABE, Delmar, NY (US)

(73) Assignee: HITACHI, LTD.

(21) Appl. No.: 12/555,778

(22) Filed: Sep. 8, 2009

(51) Int. Cl. G11C 11/00; G11C 7/00

(52) U.S. Cl. 365/163; 365/189.011; 365/189.2

(57) ABSTRACT

A random-access non-volatile semiconductor memory device, which does not use individual gate terminals of transistors of memory cells in order to select individual memory cells for read/write operations performed on the device. The gate terminals of the memory cells are all biased to the same voltage during a read or write operation. For example, the gate terminals of the memory cells in the array are electrically connected together. By appropriate control of source and drain voltages during a read or write operation, discrimination can be achieved between selected and non-selected memory cells of the array.

### TECHNICAL FIELD

The present application relates generally to semiconductor memory devices, and, more particularly, to a random access non-volatile memory array.

### BACKGROUND

A conventional random-access non-volatile memory cell array 900 is schematically illustrated in FIG. 24. In such a device, a memory cell 902 in the array 900 is selected by applying appropriate voltages to the gate 908 of the selected memory cell 902 through a respective one of a plurality of gate lines 916a-e and to the drain 904 of the selected memory cell 902 through a respective one of a plurality of bit lines 914a-e. An appropriate voltage is applied simultaneously to the sources 906 of the memory cells by a common source line 912. Information stored in the selected memory cell 902 can be read out from the charge storage region 910 by sensing the current flowing between the respective source 906 and the drain 904 of the memory cell transistor.

To reduce the size of memory cells in the array, it is necessary to minimize the size of each transistor. However, as the size of the transistor is reduced, the distance between the source 906 and the drain 904 is decreased, thereby resulting in an increase in leakage current in the transistor. Because of the leakage current due to this “short channel effect,” the ability of the gate 908 to control current flow between the source 906 and the drain 904 of the transistor is compromised. Thus, the information stored in a selected memory cell cannot be read out.

For single transistors, tuning of the impurity profile in the semiconductor substrate can be used to reduce the leakage current, but as transistor size decreases, the tuning of the impurity profile becomes increasingly difficult. Instead of impurity profile tuning, an additional select transistor can be used in each memory cell to suppress leakage current. However, this extra transistor in each memory cell may increase the physical size of each memory cell and thus negate any space and cost savings afforded by reducing the size of the memory cell transistor.

Accordingly, there is a need for a non-volatile memory cell that is capable of being scaled down in physical size while minimizing leakage current in the non-volatile memory cell.

### SUMMARY

Embodiments of the present invention may address the above-mentioned problems and limitations, among other things.

In embodiments, a random-access non-volatile semiconductor memory device does not use individual gate terminals of transistors of memory cells in order to select individual memory cells. Rather, the gate terminals of all memory cells are biased to the same voltage during a read or write operation. In some embodiments, the gate terminals of the memory cells are all connected together. In such embodiments, appropriate control of source and drain voltages provides the necessary discrimination between selected and non-selected memory cells during read and write operations. Thus, the ability of the gate to control current flowing between the source and drain voltages in the presence of the short channel effect is maintained.

In embodiments, a non-volatile memory device includes a plurality of memory cells arranged in a rectangular array with rows and columns. Each memory cell includes a transistor having a source, a drain, and a gate. Each memory cell also includes a charge storage region, such as a silicon oxide/silicon nitride/silicon oxide (ONO) charge storage layer or a phase change material. Source lines connect together the sources of the transistors in a same row, while bit lines connect together the drains of the transistors in a same column.

In embodiments, read or write operations in the non-volatile memory array are accomplished by applying appropriate voltages for the read/write operation to a selected source line and a selected drain line. A gate voltage for the read/write operation is then applied to the gate line. The desired operation can then be performed on the memory cell connected to the selected source and drain lines. By applying appropriate inhibit voltages to the non-selected source and bit lines, the read/write operation is prevented from being performed inadvertently on the non-selected memory cells (e.g., those connected to the non-selected source and bit lines) even when a gate voltage is applied to the gates of the non-selected memory cells.

### BRIEF DESCRIPTION OF THE DRAWINGS

The foregoing and other aspects, features and advantages of the present invention will be better appreciated from the following description of the preferred embodiments, considered with reference to the accompanying drawings, wherein:

FIG. 1 is a schematic of a non-volatile memory cell array according to first and second embodiments of the present invention;

FIG. 2A is a diagram showing respective voltage levels applied to a non-volatile memory cell array during a read operation;

FIG. 2B is a schematic of a non-volatile memory cell array during a read operation;

FIG. 3A is a diagram of a selected memory cell in a non-volatile memory cell array during a read operation;

FIG. 3B is a graph showing the relationship of voltages applied to the source and the drain in a memory cell;

FIG. 4A is a diagram showing respective voltage levels applied to a non-volatile memory cell array during a write operation;

FIG. 4B is a schematic of a non-volatile memory cell array during a write operation;

FIG. 5 is a diagram showing respective voltage levels applied to a non-volatile memory cell array during an erase operation;

FIGS. 6A-6B are plan and cross-sectional views, respectively, after a first step in a fabrication process for the non-volatile memory cell array according to a first embodiment of the present invention;

FIGS. 7A-7B are plan and cross-sectional views, respectively, after a second step in a fabrication process for the non-volatile memory cell array according to the first embodiment of the present invention;

FIGS. 8A-8B are plan and cross-sectional views, respectively, after a third step in a fabrication process for the non-volatile memory cell array according to the first embodiment of the present invention;

FIGS. 9A-9B are plan and cross-sectional views, respectively, after a fourth step in a fabrication process for the non-volatile memory cell array according to the first embodiment of the present invention;

FIGS. 10A-10B are plan and cross-sectional views, respectively, after a fifth step in a fabrication process for the non-volatile memory cell array according to the first embodiment of the present invention;

FIGS. 11A-11B are plan and cross-sectional views, respectively, after a sixth step in a fabrication process for the non-volatile memory cell array according to the first embodiment of the present invention;

FIGS. 12A-12B are plan and cross-sectional views, respectively, after a seventh step in a fabrication process for the non-volatile memory cell array according to the first embodiment of the present invention;

FIGS. 13A-13B are plan and cross-sectional views, respectively, after an eight step in a fabrication process for the non-volatile memory cell array according to the first embodiment of the present invention;

FIGS. 14A-14B are plan and cross-sectional views, respectively, after a ninth step in a fabrication process for the non-volatile memory cell array according to the first embodiment of the present invention;

FIGS. 15A-15B are plan and cross-sectional views, respectively, after a tenth step in a fabrication process for the non-volatile memory cell array according to the first embodiment of the present invention;

FIGS. 16A-16B are plan and cross-sectional views, respectively, after an eleventh step in a fabrication process for the non-volatile memory cell array according to the first embodiment of the present invention;

FIGS. 17A-17B are plan and cross-sectional views, respectively, after a first step in a fabrication process for the non-volatile memory cell array according to the second embodiment of the present invention;

FIGS. 18A-18B are plan and cross-sectional views, respectively, after a second step in a fabrication process for the non-volatile memory cell array according to the second embodiment of the present invention;

FIGS. 19A-19B are plan and cross-sectional views, respectively, after a third step in a fabrication process for the non-volatile memory cell array according to the second embodiment of the present invention;

FIGS. 20A-20B are plan and cross-sectional views, respectively, after a fourth step in a fabrication process for the non-volatile memory cell array according to the second embodiment of the present invention;

FIGS. 21A-21B are plan and cross-sectional views, respectively, after a fifth step in a fabrication process for the non-volatile memory cell array according to the second embodiment of the present invention;

FIGS. 22A-22B are plan and cross-sectional views, respectively, after a sixth step in a fabrication process for the non-volatile memory cell array according to the second embodiment of the present invention;

FIG. 23 is a schematic of a non-volatile memory cell array according to a third embodiment of the present invention; and

FIG. 24 is a schematic of a conventional non-volatile memory cell array.

### DETAILED DESCRIPTION

Embodiments of the present invention will hereinafter be described in detail with reference to the accompanying drawings, wherein like reference numerals represent like elements. The accompanying drawings have not been drawn to scale. Where applicable some features have not been illustrated to assist in the description of the underlying features.

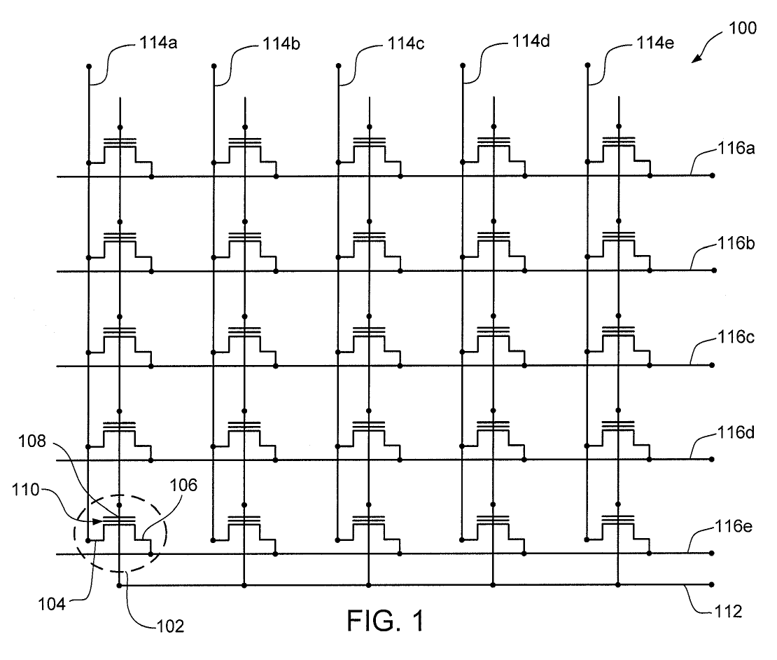

FIG. 1 is a schematic of a non-volatile memory cell array 100 according to an embodiment of the present invention. In such embodiments, the non-volatile memory cell array 100 is a rectangular array of individual memory cells 102 arranged in rows and columns. Each memory cell 102 includes an information storage region. For example, the memory cell 102 is an ONO-type non-volatile memory cell where information is represented as an amount of charge stored in a silicon oxide/silicon nitride/silicon oxide film 110 arranged between the gate 108 and the channel of the transistor in each memory cell 102.

The memory array 100 also includes a plurality of source lines 116a-116e. Each source line 116 connects the sources 106 of a plurality of memory cells 102 disposed in a first row in a first direction. For example, the memory cells 102 in a first row have their sources 106 connected together by a common source line 116a. Similarly, the memory cells 102 arranged in the other rows have their respective sources 106 connected together by common source lines 116b-116e, respectively.

The memory array 100 further includes a plurality of bit lines 114a-114e. Each bit line 114 is connected to the drains 104 of a plurality of memory cells 102 disposed in a second direction different from the first direction. The second direction is preferably perpendicular to the first direction. For example, the memory cells 102 in a first column have their drains 104 connected together by a common bit line 114a. Similarly, the memory cells 102 arranged in other columns have their respective drains 104 connected together by common bit lines 114b-114e, respectively.

The gates 108 of the memory cells 102 in the array 100 are connected such that the same voltage can be applied to all of the gates 108 during an operation performed on the array 100. For example, each gate 108 is connected to a common gate line 112. Alternatively, the gates 108 of memory cells 102 in a particular row or column are connected together. In yet another alternative, each gate 108 is connected so as to be independently controllable from the other gates, but controlled together to have the same gate voltage during a read or write operation on the non-volatile memory array 100.

Because selection of the gate 108 in a memory cell 102 is not necessary to select that memory cell for a particular operation from others in the memory cell array 100, the operation can be performed on the selected memory cell 102 even if the gate 108 of the selected memory cell 102 cannot control the current between the source 106 and the drain 104 due to the short channel effect. Thus, the memory cell can be reduced in size without a corresponding loss in operability of the memory cell.

### Read Operation

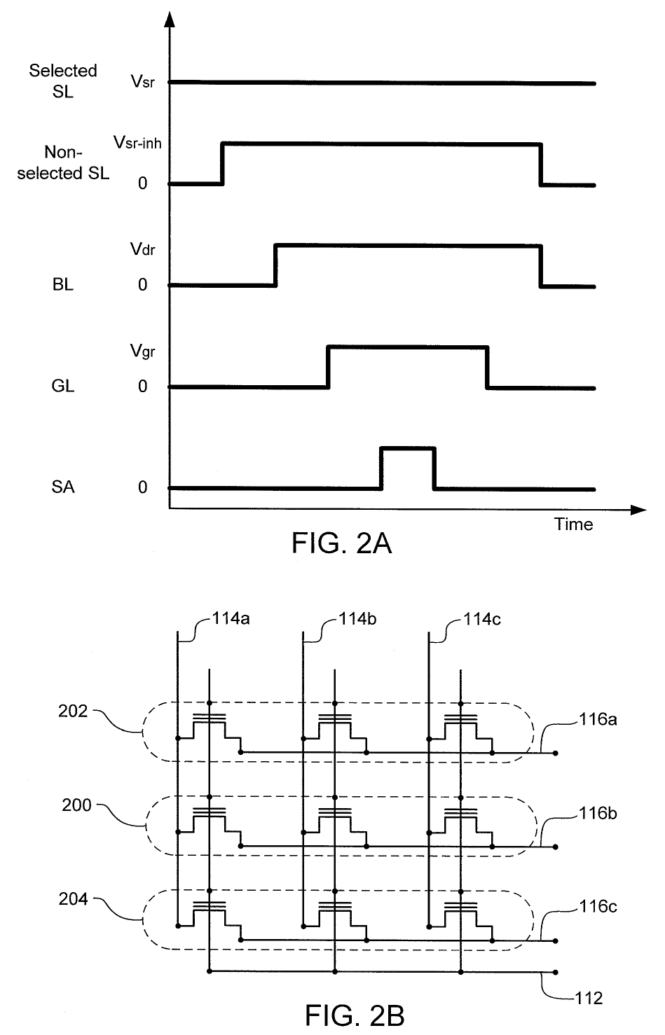

FIG. 2A is a diagram showing respective voltage levels applied to a non-volatile memory cell array during a read operation. FIG. 2B is a schematic of a non-volatile memory cell array during a read operation.

In order to read information stored in the memory array, a row of memory cells is selected for the read operation. The selected memory cells include all the memory cells in a particular row. For example, the memory cells in row 200 are selected while the memory cells in rows 202, 204 are designated as non-selected.

A source line read-out voltage, Vₛᵣ, is applied to the source line 116b associated with the selected row 200. A source line inhibit voltage, Vₛᵣ₋ᵢₙₕ, is applied to the source line 116a and source line 116c, which are associated with non-selected rows 202 and 204, respectively. After the source line voltages are applied, a bit line read-out voltage, V_{dr}, is applied to all bit lines 114a-114c regardless of the location of the selected memory cells.

A gate line read-out voltage, V_{gr}, is then applied to all gates of the memory cells via the common gate line 112. FIG. 2A shows the timing of the voltages. In this example, Vₛᵣ is 0.0V, V_{dr} is 1.0V, and Vₛᵣ₋ᵢₙₕ is 1.0V and V_{gr} is 1.0V. However, other voltages are also possible within the context of the present invention.

The selected memory cells connected to source line 116b are selected for read-out operation by virtue of the read-out voltages Vₛᵣ and V_{dr}. The resulting current flowing in each bit line 114a-114c can thus be sensed to read out the information in each memory cell in the selected row 200 simultaneously. A current-sense amplifier is provided for each bit line 114a-114c to detect the current flowing therethrough. Because cells in a row can be simultaneously read, the time required for reading multiple cells of the non-volatile memory array can be substantially reduced to the time required to read one of the memory cells.

If the threshold voltage of the selected memory cells is in a low state, current flows in the respective bit line connected to the selected memory cells. If the threshold voltage of the selected memory cells is in a high state, current does not flow in the respective bit line.

While current is allowed to flow in the selected memory cells in row 200 of the array, current is prevented from flowing in the non-selected memory cells in rows 202, 204 by selecting the applied voltages for the source and drain such that current will not flow therebetween even if the gate voltage takes an “on” state. For example, current is prevented from flowing between the source and the drain if the following conditions are met:

V_{gr}−Vₜₕ<Vₛᵣ₋ᵢₙₕ (for Vₛᵣ₋ᵢₙₕ<V_{dr}) (1)

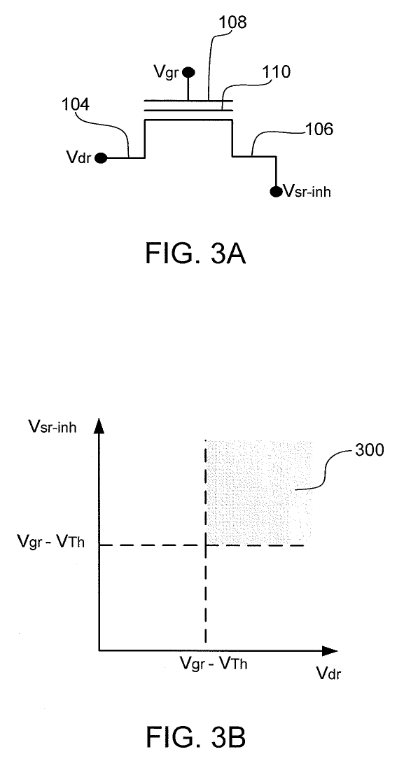

V_{gr}−Vₜₕ<V_{dr} (for V_{dr}<Vₛᵣ₋ᵢₙₕ) (2)

where Vₜₕ is the threshold voltage of the transistor, V_{gr} is the gate line read-out voltage applied to gate 108, Vₛᵣ₋ᵢₙₕ is the source line inhibit voltage applied to the source 106, and V_{dr} is the drain line read-out voltage applied to the drain 104 of the non-selected memory cell (FIG. 3A). The above-criteria are illustrated graphically in FIG. 3B, where region 300 represents the values for V_{dr} and Vₛᵣ₋ᵢₙₕ where current will not flow in non-selected memory cells. Accordingly, as long as Vₛᵣ₋ᵢₙₕ and V_{dr} satisfy the above conditions, current will not flow in the non-selected memory cells.

Based on equations (1) and (2) above, Vₛᵣ₋ᵢₙₕ and V_{dr} need not be equal to each other for current to be prevented from flowing in the non-selected memory cells. However, the values for Vₛᵣ₋ᵢₙₕ and V_{dr} are preferably equal to each other so as to minimize the number of voltages necessary for operation of the memory cell array, thereby simplifying the design of any accompanying power supply circuitry.

The lowest value for the threshold voltage, Vₜₕ, is dictated by the requirements of the erase operation. In particular, V_{gr} is set such that

V_{gr}−Vₜₕ<Vₛᵣ₋ᵢₙₕ. (3)

The above description has inhibit voltages applied to non-selected source lines, a read-out voltage applied to a selected source line, and a common read-out voltage applied to all bit lines in order to effect read-out from a selected row of memory cells. However, a similar process is also available for simultaneously reading out information from a selected column of memory cells. In this example, inhibit voltages are applied to non-selected bit lines, a read-out voltage is applied to a selected bit line, and a common read-out voltage is applied to all source lines in order to effect read-out from a selected column of memory cells. In both examples, a common gate voltage is applied to all the gates of the memory array during the read operation.

### Write Operation

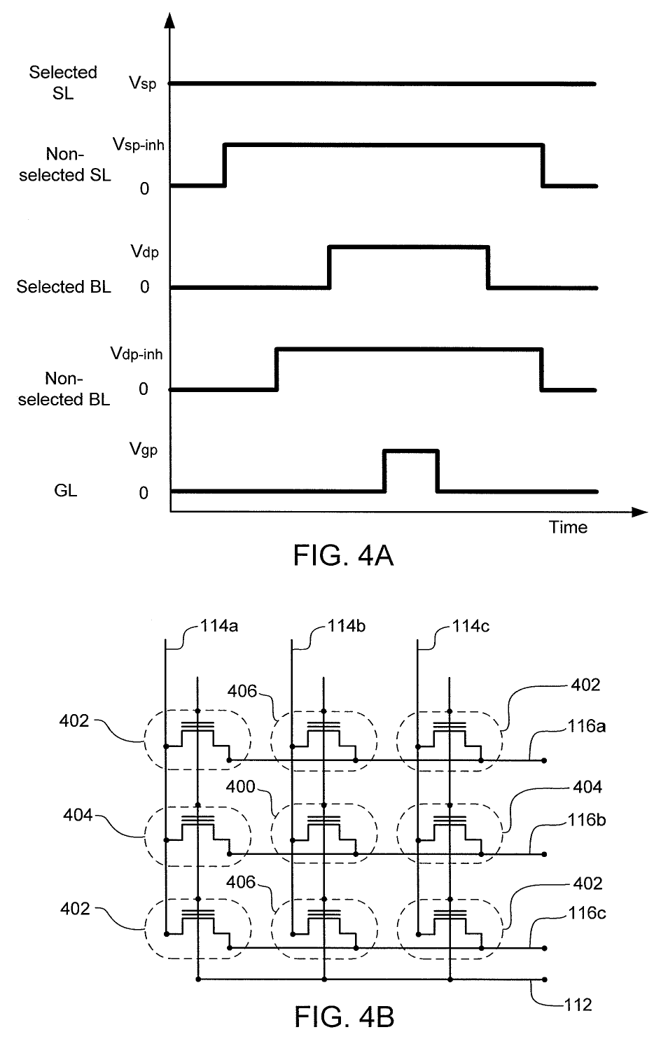

FIG. 4A is a diagram showing the respective voltage levels applied to a non-volatile memory cell array during a write operation. FIG. 4B is a schematic of a non-volatile memory cell array during a write operation.

Programming or writing of a memory cell is accomplished using channel-hot-electron injection (CHEI). First, a memory cell 400 is selected for programming. The corresponding source line 114b is then selected. A source line program voltage, Vₛₚ, is applied to the selected source line 114b. A source line inhibit voltage, Vₛₚ₋ᵢₙₕ, is applied to the non-selected source lines 114a, 114c.

The bit line 116b corresponding to the selected memory cell 400 is then selected. A drain line program voltage, V_{dp}, is applied to the selected bit line 116b. A drain line inhibit voltage, V_{dp-inh}, is applied to the other non-selected bit lines 116a, 116c so as to prevent the non-selected memory cells from being programmed.

When the appropriate voltages have been applied to the source and bit lines, memory cell 400 is effectively selected for programming while memory cells 402, 404, and 406 are non-selected. A gate line program voltage, V_{gp}, is then applied to all the gates in the array via the gate line 112. High-energy charges flow from the source to the drain in the selected memory cell 400. Some of these high-energy charges are injected into the charge storage region 110 (FIG. 1). The injected charges shift the threshold voltage of the selected memory cell 400. This shifted threshold voltage represents the programmed information.

While the inhibit voltages applied to the source and drain lines are designed to prevent programming of non-selected memory cells, it is not necessary to prevent current from flowing through the non-selected memory cells upon application of the program voltage to the gate line 112. Rather, during programming, current can flow in the unselected memory cells but at a level that is insufficient to cause programming of the non-selected memory cells.

The same inhibit voltage as that employed in the reading operation (e.g., Vₛᵣ₋ᵢₙₕ) could be used in the programming operation to prevent current from flowing in non-selected memory cells. However, to use the same inhibit voltage, the writing operation would need to satisfy equation (3). For example, a voltage configuration of CHEI for a selected memory cell in the write operation is V_{g}=10V, Vₛ=0V, V_{d}=4V, initial Vₜₕ=2V (i.e., prior to any CHEI), and V_{critical}≈3V. Thus, Vₛ₋ᵢₙₕ>10V−2V=8V. Such a value may be high from the reliability standpoint for use in a non-volatile memory array.

However, in CHEI, the efficiency of injection is sensitive to the voltage difference, V_{Δ}, between the source and the drain. If V_{Δ} is less than the critical voltage for injection (i.e., V_{critical}), charge will not be injected into the non-selected memory cells, thereby preventing programming. Thus, inhibit voltages can be selected for the source and bit lines which prevent information injection even though current may flow therethrough.

Referring again to FIG. 4B, selected memory cell 400 has a source line programming voltage, Vₛₚ, via source line 116b and a drain line programming voltage, V_{dp}, via bit line 114b. The programming voltages are chosen such that:

V_{Δ}=V_{dp}−Vₛₚ>V_{critical}. (4)

Thus, current will flow through memory cell 400 and charges will be injected into the charge storage layer via CHEI.

The source line inhibit voltage, Vₛₚ₋ᵢₙₕ, is applied to non-selected source lines 116a and 116c. Similarly, the drain line inhibit voltage, V_{dp-inh}, is applied to non-selected bit lines 114a and 114c. Non-selected memory cells 402 thus have respective inhibit voltages applied to both their sources and drains. The voltages are chosen such that:

V_{Δ}=V_{dp-inh}−Vₛₚ₋ᵢₙₕ<V_{critical}. (5)

If VΔ≠0, then current may flow between the source and the drain of non-selected memory cells 402 (depending on the gate and threshold voltages), but injection of electrons into charge storage regions of non-selected memory cells 402 will not occur.

Non-selected memory cells 404 have the drain line inhibit voltage, V_{dp-inh}, applied to their drains through respective bit lines 114a, 114c while the source line programming voltage, Vₛₚ, is applied to their sources through source line 116b. The voltages are chosen such that:

V_{Δ}=V_{dp-inh}−Vₛₚ<V_{critical}. (6)

If V_{Δ}≠0, then current may flow between the source and the drain of non-selected memory cells 404 (depending on the gate and threshold voltages), but injection of electrons into charge storage regions of non-selected memory cells 404 does not occur.

Non-selected memory cells 406 have the source line inhibit voltage, Vₛᵣ₋ᵢₙₕ, applied to their respective sources through respective source lines 116a, 116c while the drain line programming voltage, V_{dp}, is applied to their drains through bit line 114b. The voltages are chosen such that:

V_{Δ}=V_{dp}−Vₛₚ₋ᵢₙₕ<V_{critical}. (7)

If VΔ≠0, then current may flow between the source and the drain of non-selected memory cells 406 (depending on the gate and threshold voltages), but injection of electrons into charge storage regions of non-selected memory cells 406 does not occur.

The voltage configuration for the programming operation is preferably Vₛₚ=0V and V_{dp-inh}=Vₛₚ₋ᵢₙₕ=V_{dp}/2 thereby minimizing the number of voltages employed in operation of the memory cell array. For example, a suitable voltage configuration is Vₛₚ=0, V_{dp}=4V, V_{gp}=10V, Vₜₕ=2V, V_{dp-inh}=2V, and Vₛₚ₋ᵢₙₕ=2V.

### Erase Operation

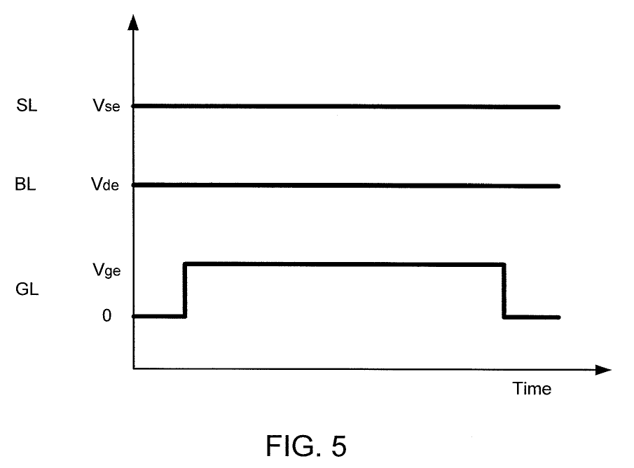

FIG. 5 is a diagram showing respective voltage levels applied to a non-volatile memory cell array during an erase operation.

The erase operation is accomplished by applying a bit line erase voltage, V_{de}, and a source line erase voltage, Vₛₑ, to all bit lines and source lines, respectively. A gate erase voltage, V_{ge}, is then applied to all of the gates in the memory cell array. For example, V_{de}=0V, Vₛₑ=0V, and V_{ge}=15V. With this voltage configuration, all the charges stored in the charge storage region 110 of each memory cell 102 are erased simultaneously.

### Embodiment 1

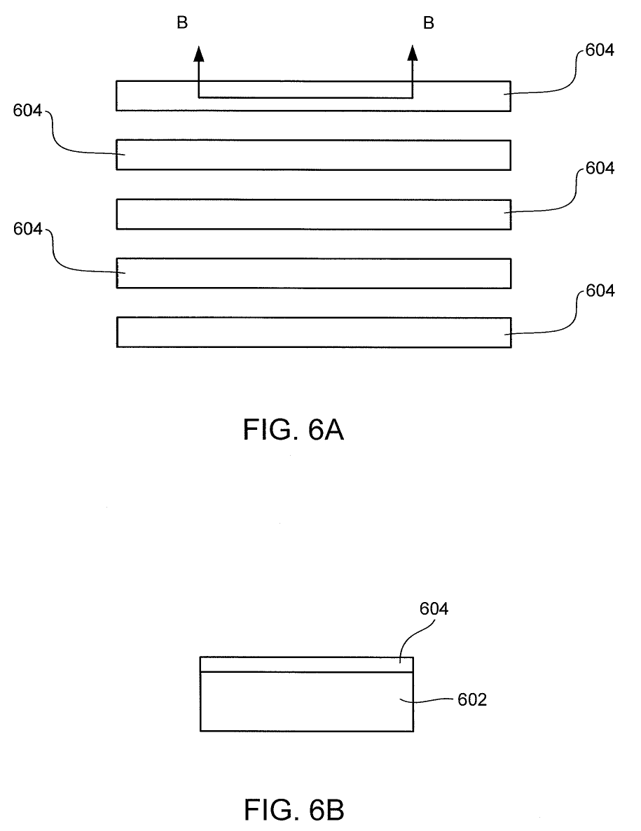

FIGS. 6A-16B show a fabrication process for the non-volatile memory cell array according to a first embodiment of the present invention. The “A” figures illustrate plan views of a step in the fabrication process. In the figures, not all layers are shown for clarity in illustration and description of the underlying features. The “B” figures illustrate cross-sectional views along line B-B in the corresponding figure “A”. In the figures, not all layers have been shown in plan view for clarity.

Referring initially to FIGS. 6A-6B, ion implantation is performed on a semiconductor substrate 602, such as a silicon wafer, to form wells therein. After the implantation, a layer of silicon nitride 604 is deposited on the substrate 602 and patterned. The patterning of the silicon nitride 604 is achieved using photolithography and etching, for example.

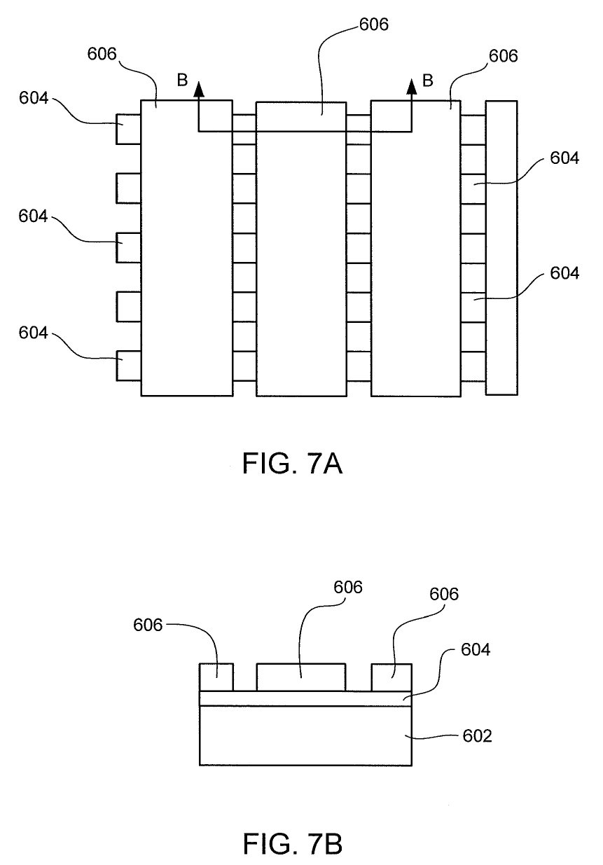

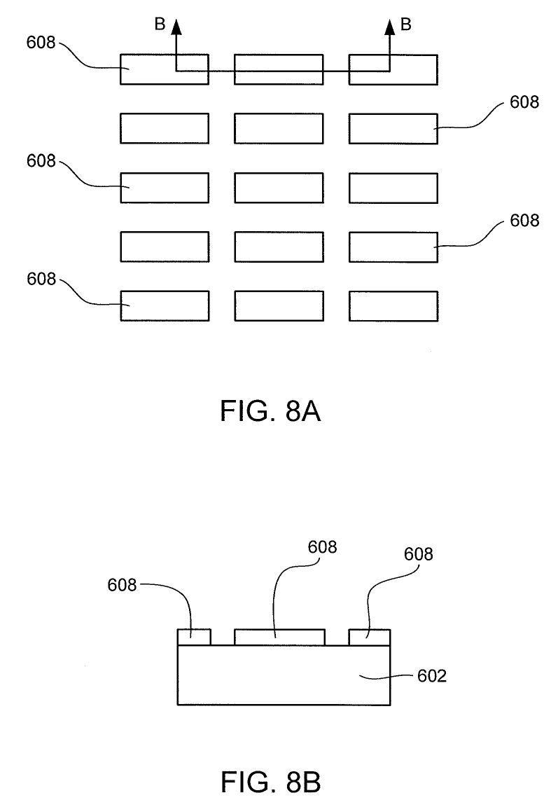

Referring to FIGS. 7A-7B, a cut mask 606 is formed over the patterned silicon nitride layer 604 to define active regions. With the use of the cut mask 606, the silicon nitride layer 604 is further patterned into silicon nitride portions 608, as shown in FIGS. 8A-8B. It is also possible to form the silicon nitride portions 608 in a single patterning step.

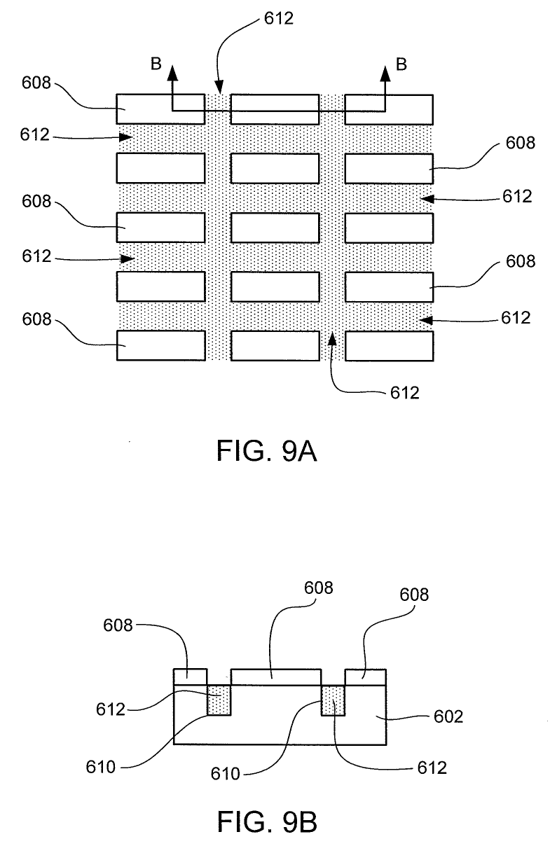

These silicon nitride portions 608 serve as etch mask for subsequent steps. In particular, the substrate 602 is etched using the silicon nitride portions 608 as a mask to form isolation trenches in the substrate between the silicon nitride portions 608. After formation of the trenches 610, a dielectric is formed in the trenches 610 to form trench isolations 612, as shown in FIGS. 9A-9B. This process forms the active area for the formation of the memory cells (defined by silicon nitride portions 608) and the trench isolations 612.

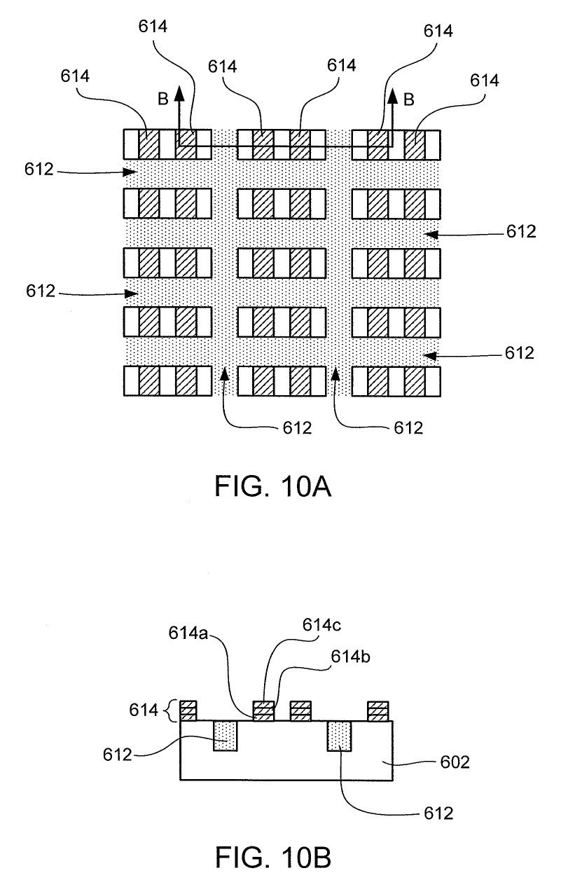

Referring to FIGS. 10A-10B, the silicon nitride portions 608 are removed and a charge storage film 614 is deposited and patterned. The charge storage film 614 includes a bottom film 614a of silicon oxide, an intermediate film 614b of silicon nitride, and a top film 614c of silicon oxide.

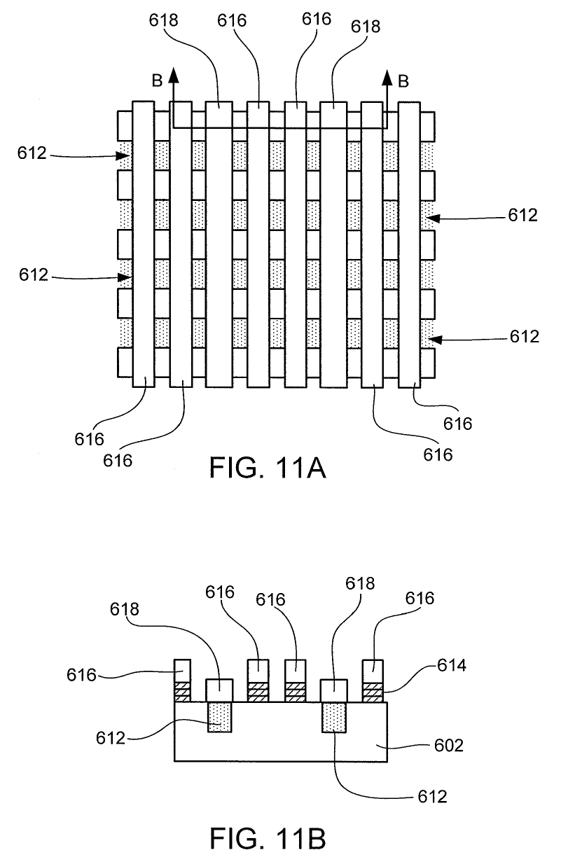

Gate material, for example, amorphous silicon, is then deposited over the substrate 602 and patterned to form gate electrodes 616 over the charge storage film 614, as shown in FIGS. 11A-11B. The charge storage film 614 can be patterned prior to deposition of the gate material 616 or simultaneously with the patterning of the gate material 616.

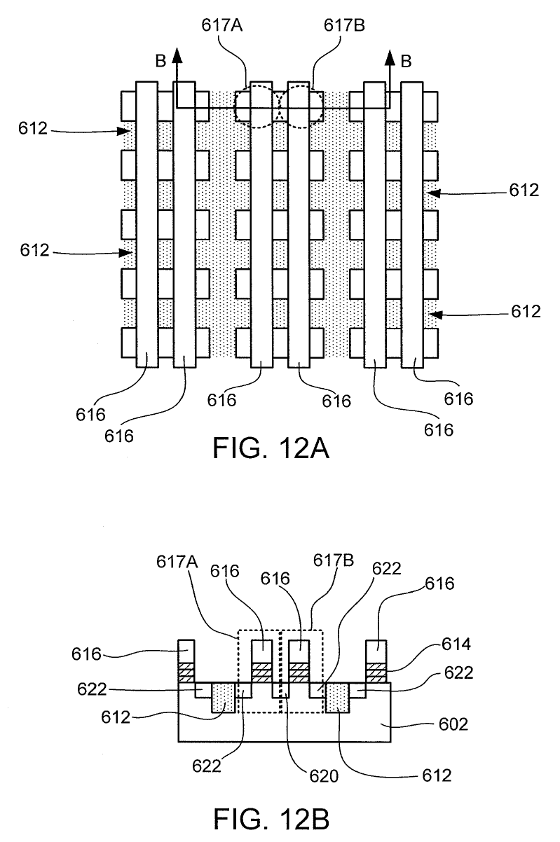

The deposition and patterning of the gate material also forms gate material portions 618 over isolation trenches 612, as shown in FIGS. 11A-11B. Subsequent patterning is performed to remove material 618 thereby resulting in the illustrated configuration in FIG. 12A.

Referring now to FIGS. 12A-12B, ion implantation is performed to form source regions 620 between adjacent gate electrodes 616 and to form drain regions 622 between a gate electrode 616. Successive thermal process activates the implanted ion. Thus, two transistors 617a, 617b are formed for each active region and share a common source region 620.

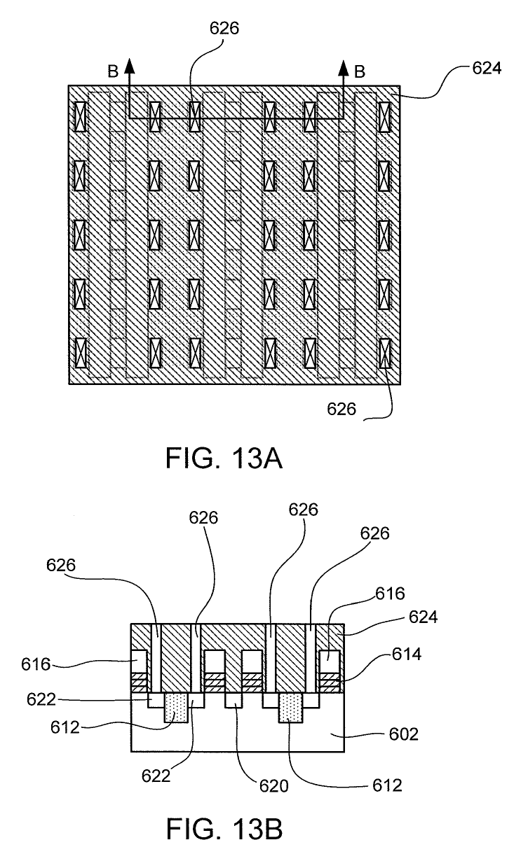

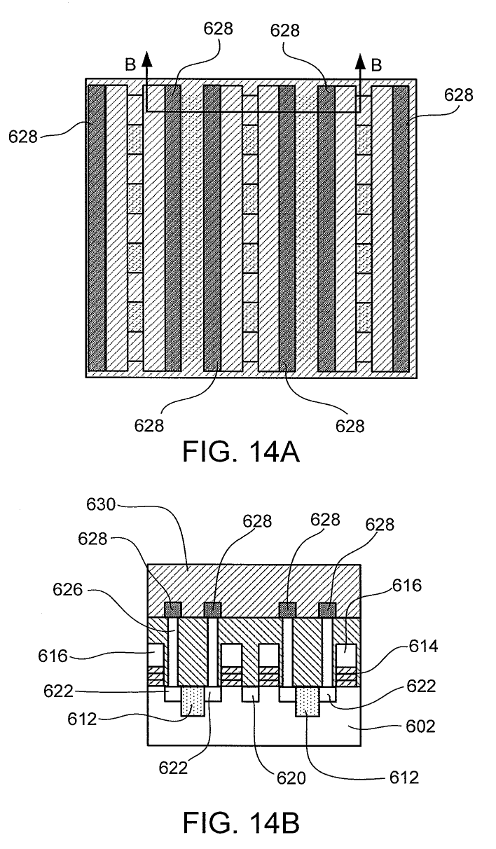

Referring to FIGS. 13A-13B, a first insulating film 624 is deposited over the entire device and planarized. Conductive vias 626 are formed in the first insulating film 624 so as to electrically connect to the drains 622 of the memory cell transistors. A plurality of bit lines 628 are subsequently formed over the vias 626 in a column direction, as shown in FIGS. 14A-14B. Each bit line 628 connects vias 626 in the column direction together. The bit lines 628 and vias 626 are formed from copper, for example.

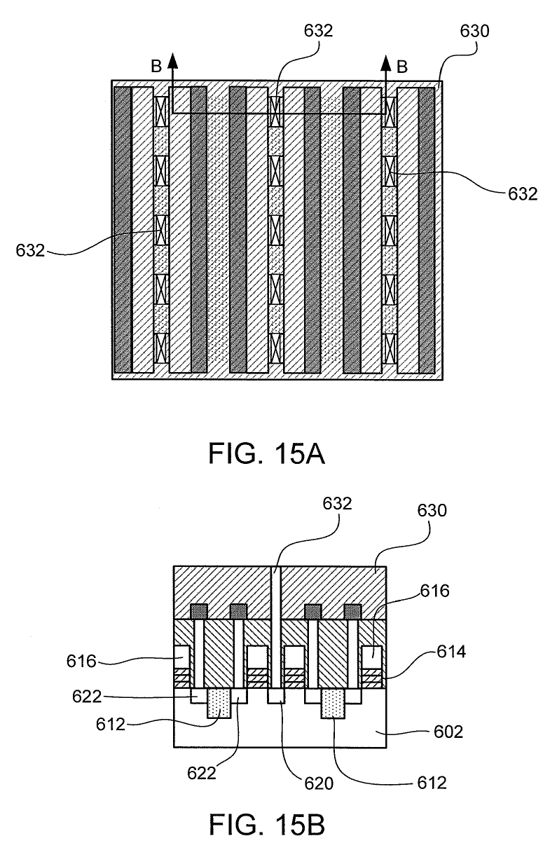

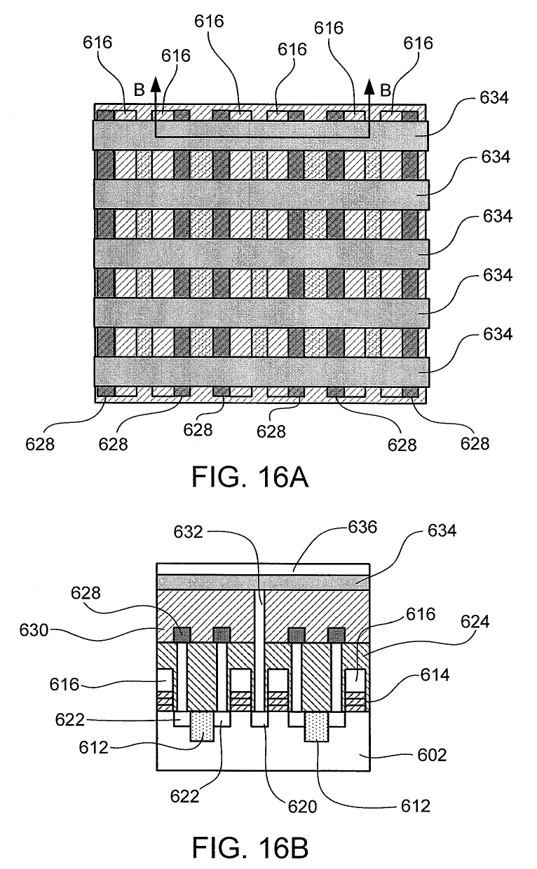

Referring to FIGS. 15A-15B, a second insulating film 630 is deposited over the entire device and planarized. Conductive vias 632 are formed in both the first insulating film 624 and the second insulating film 630 so as to electrically connect to the sources 620 of the memory cell transistors. A plurality of source lines 634 are subsequently formed over the vias 632 in a row direction, as shown in FIGS. 16A-16B. Each source line 634 connects the vias 632 in the row direction together. The source lines 634 and vias 632 are formed from copper, for example.

After forming the source lines, any necessary additional insulating films are deposited. For example, a third insulating film 636 can be deposited over the entire device to protect the source lines 634. Moreover, any necessary metal lines, such as needed for electrical contact and power, are formed after formation of the source lines to complete fabrication of the non-volatile memory device.

### Embodiment 2

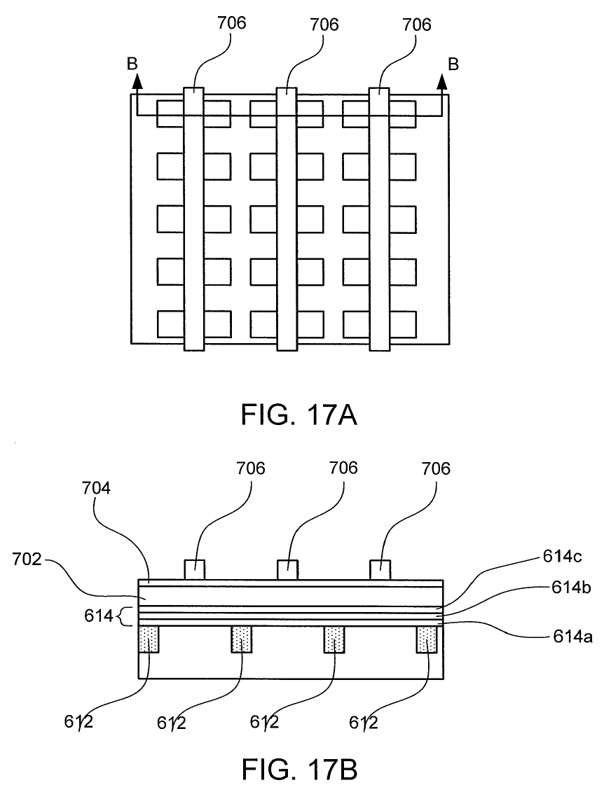

FIGS. 17A-22B show a fabrication process for the non-volatile memory cell array according to a second embodiment of the present invention. The “A” figures illustrate plan views of a step in the fabrication process. In the figures, not all layers are shown for clarity in illustration and description of the underlying features. The “B” figures illustrate cross-sectional views along line B-B in the corresponding figure “A”. In the figures, not all layers have been shown in plan view for clarity.

The circuit diagram of the non-volatile memory array according to the second embodiment is the same as in the first embodiment (i.e., FIG. 1). Moreover, the fabrication process is similar to that of the first embodiment but has been altered to form the gate electrode and the charge storage layer using a side-wall self-alignment process.

The fabrication steps of the first embodiment prior to the patterning of the charge storage layer (e.g., FIGS. 6A-10B) are applicable to the second embodiment. However, after the deposition of the charge storage layer 614 but before any patterning thereof, a gate material 702 is deposited over the charge storage layer 614, as shown in FIGS. 17A-17B. The gate material 702 is, for example, amorphous silicon.

A first hard mask layer 704 is deposited over the gate material 702. A second hard mask layer 706 is then deposited over the first hard mask layer 704. For example, the first hard mask layer is silicon oxide and the second hard mask layer 706 is amorphous silicon. The second hard mask layer 706 is patterned as shown in FIGS. 17A-17B.

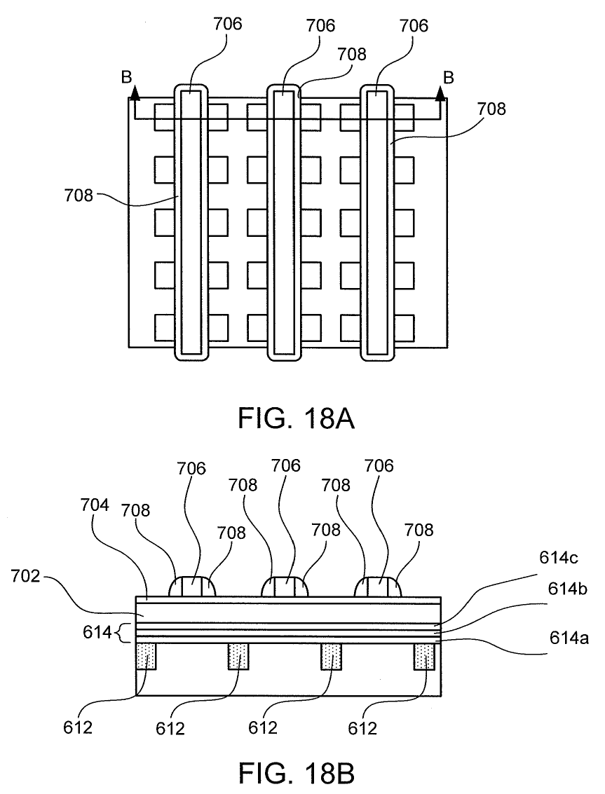

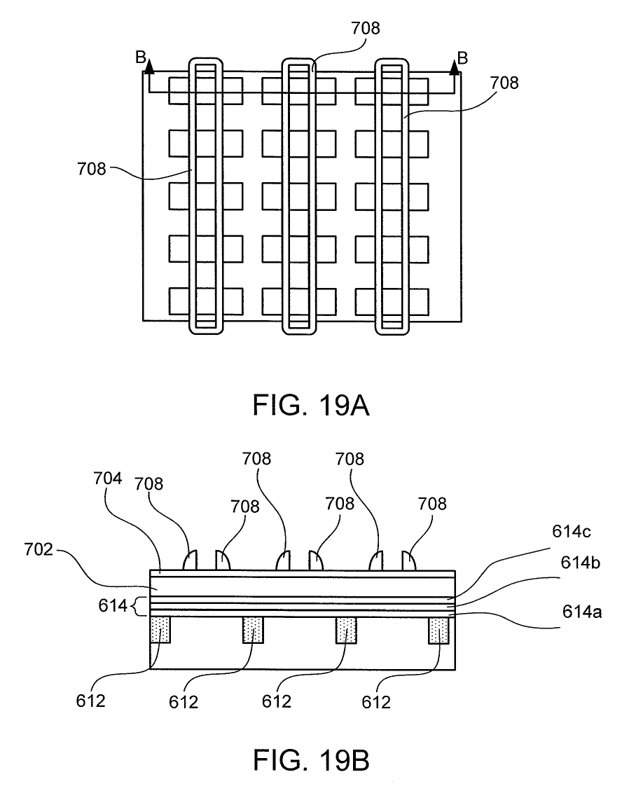

After the patterning of the second hard mask layer, a side-wall film is deposited and etched back. This process forms side-wall structures 708, as shown in FIGS. 18A-18B. The side-wall structures 708 are formed of, for example, silicon oxide. Referring to FIGS. 19A-19B, the second hard mask layer 706 is subsequently removed by selective etching leaving side-wall structures 708 in place.

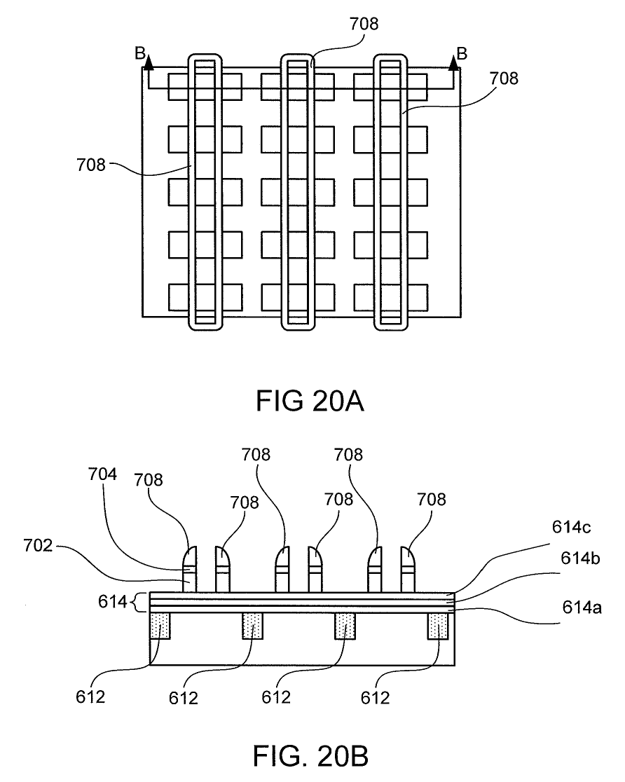

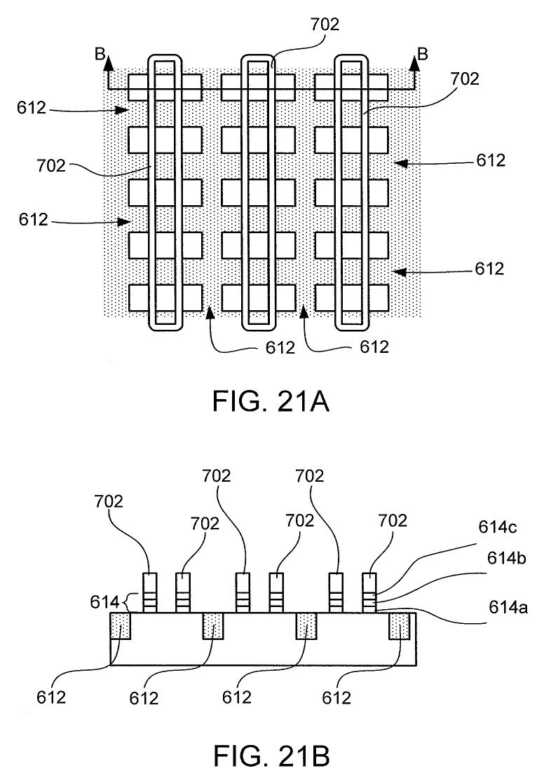

The side-wall structures 708 serve as a mask for subsequent etching steps of the first mask layer 704 and the gate material 702. The etch of the first mask layer 704 and the gate material 702 forms the gate electrodes from the gate material 702, as shown in FIGS. 20A-20B. The first mask layer 704 is then removed leaving the gate electrode 702 and the charge storage layer 614 formed in place, as shown in FIGS. 21A-21B.

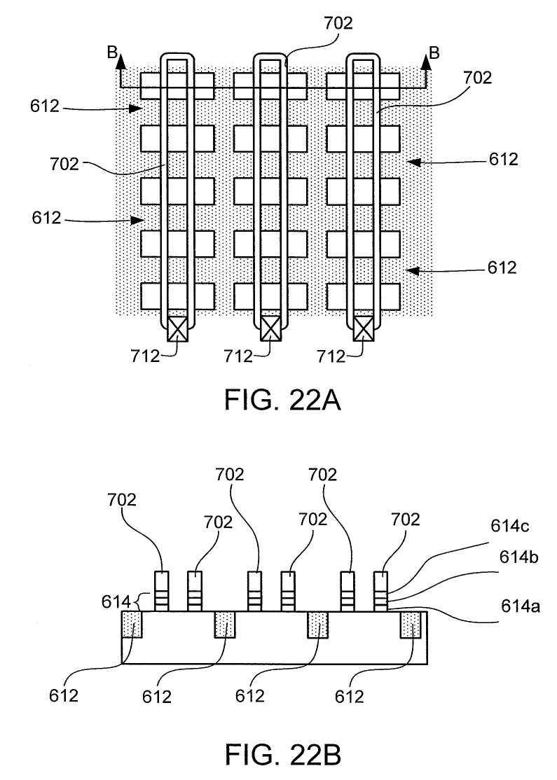

By using this self-alignment process, gate electrodes can be fabricated with finer pitch and thinner width as compared to the first embodiment. As shown in FIG. 21A, the resulting gate electrodes 702 has a ring shape. Electrical connection to the gates of each memory cell are provided by contact 712 connected to each ring-shaped gate electrode 702, as shown in FIG. 22A-22B.

Since a common voltage is applied to all gate electrodes in the non-volatile memory array when performing an operation on memory cells in the non-volatile memory array, it is not necessary to isolate the individual gate electrodes from each other by cutting the ring-shaped gate 702. In addition, there is no need to form individual contacts to each gate electrode because of the common gate voltage. In general, if lines are formed which have a finer pitch than a pitch that the lithographic patterning is capable of, it is not easy to provide a contact to those lines. However, in this configuration, a single gate contact 712 for each gate electrode ring 702 is sufficient, thereby simplifying the fabrication process. With this side-wall self-alignment process, finer and thinner gate electrodes can be produced which thereby reduces the size of the memory cells and achieves a lower fabrication cost.

### Embodiment 3

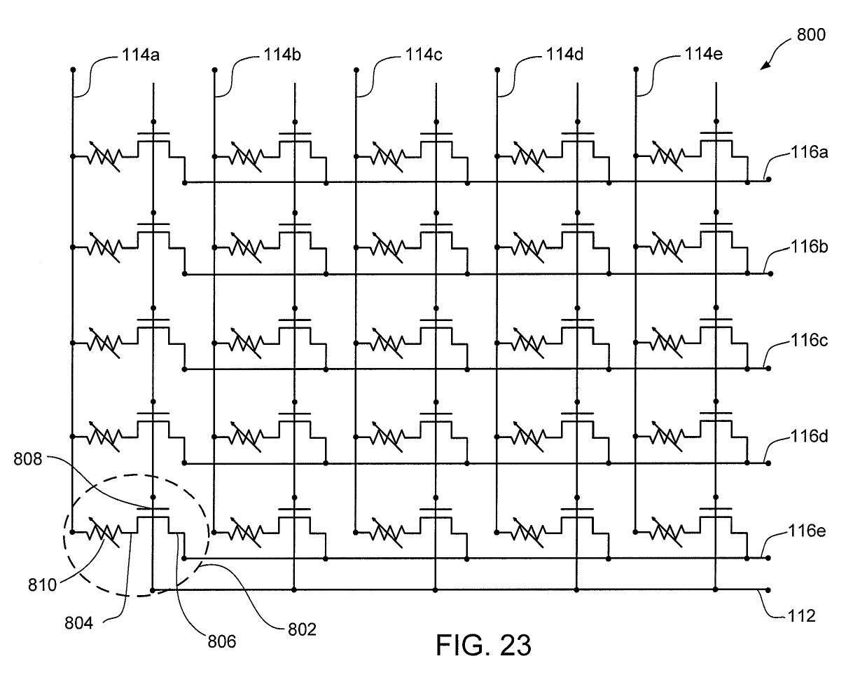

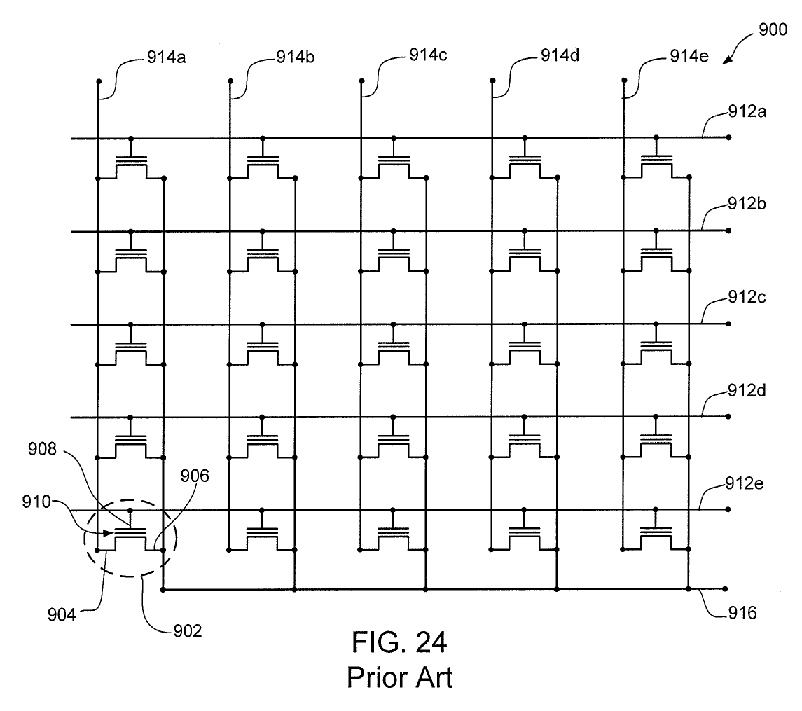

FIG. 23 is a schematic of a non-volatile memory cell array according to the third embodiment of the present invention.

In the third embodiment, the array 800 is similar to that of the first and second embodiments, as shown in FIG. 1. However, the individual memory cells 802 are different than that of the first and second embodiments. In particular, the memory cell 802 includes a transistor with a source 806, a drain 804, and a gate 808. The memory cell 802 also includes a variable resistance element 810 for storing information. For example, the variable resistance element 810 is a phase change material that stores information based on the change of resistance due to a change in phase of the material.

A plurality of source lines 116a-116e connects respective sources 806 of individual memory cells 802 in a row direction. A common gate line 112 connects the gates 808 of all of the memory cells 802. A plurality of bit lines 114a-114e connects the output ends of the variable resistance elements 810 in a column direction.

Read-out of the resistance of the variable resistance elements 810 is performed in the same manner as the first and second embodiments, as described with respect to FIGS. 2A-2B. As current flow can affect the storage of information in the variable resistance element 810 of the memory cells 802 in a write and erase operation, applied write and erase voltages in the third embodiment are preferably chosen such that current does not flow through non-selected memory cells (i.e., to satisfy equations (1) and (2)).

The non-volatile memory array as disclosed herein is particularly suited for embedded memory devices in logic circuits. Since the problems due to the short-channel effect are ameliorated by the disclosed embodiments, memory cell transistors can have a shorter gate length, thereby providing a faster read-out operation suitable for high-speed logic circuits. Because cells in a row can be simultaneously read, the time required for reading multiple cells of the memory array can be greatly reduced.

The foregoing descriptions of specific embodiments of the present invention have been presented for the purposes of illustration and description. They are not intended to be exhaustive or to limit the invention to the precise forms disclosed, and many modifications and variations are possible in light of the above teachings. For example, although the non-volatile memory array has been shown in various figures as a 3×3 or 5×5 array, the present invention is understood to not be limited to this number. Moreover, even though the array has been illustrated as a rectangular array, other array configurations are also possible according to one or more contemplated embodiments.

The embodiments described herein were chosen to best illustrate the principles of the invention and its practical application and to thereby enable others skilled in the applicable arts to utilize the invention. Various embodiments with various modifications depending on the particular use are contemplated. It is thus intended that the scope of the invention be defined by the Claims appended hereto and their equivalents.

1. A non-volatile memory device comprising:
a plurality of memory cells arranged in a rectangular array with rows and columns, each said memory cell including a transistor having a source, a drain, and a gate;
a plurality of source lines, each said source line connecting together the sources of the transistors of the memory cells in a same row; and
a plurality of bit lines, each said bit line connecting together the drains of the transistors of the memory cells in a same column,
wherein the transistors are connected such that, when voltages are applied to the plurality of source lines and the plurality of bit lines in a read or write operation on selected memory cells in one of the columns, the source and the drain of non-selected memory cells in said one of the columns are at substantially the same voltage.

2. The non-volatile memory device of claim 1,
wherein each source line and each bit line are configured such that a voltage can be applied thereto independent from other source lines and other bit lines, respectively.

3. The non-volatile memory device of claim 1,
wherein the gates of the transistors in the same column are connected to each other by a common gate line.

4. The non-volatile memory device of claim 1,
wherein the gates of the transistors in adjacent columns are connected to each other by a common gate layer having a substantially closed-loop ring shape in plan view.

5. The non-volatile memory device of claim 1,
wherein all gates of the transistors in the plurality of memory cells are electrically connected to each other.

6. The non-volatile memory device of claim 1,
wherein each said memory cell includes a charge storage region arranged between the gate and a channel region between the source and the drain.

7. The non-volatile memory device of claim 6,
wherein the gates of the transistors are formed using a self-alignment process.

8. The non-volatile memory device of claim 1,
wherein each said memory cell is phase change memory cell.

9. A method for performing a read or write operation on a semiconductor device having a plurality of non-volatile memory cells, each said memory cell including a transistor with a source, a drain, and a gate, the method comprising:
applying voltages to the source and the drain of the transistor in one or more selected memory cells of the plurality of non-volatile memory cells such that current flows between the source and the drain in the one or more selected memory cells when a read voltage or a write voltage is applied to the gates of the transistors in the plurality of non-volatile memory cells; and
applying inhibit voltages to the source and the drain of the transistor in each non-selected memory cell of the plurality of non-volatile memory cells such that current does not flow between the source and the drain in the non-selected memory cell when the read voltage or the write voltage is applied to the gates of the transistors in the plurality of non-volatile memory cells.

10. The method of claim 9, further comprising:
applying a common voltage to the gates of the transistors in the plurality of non-volatile memory cells.

11. The method of claim 9, further comprising:
after the applying inhibit voltages, applying a common read voltage to each gate of the selected memory cells, the selected memory cells having their sources connected together by a common source line; and
after the applying the common read voltage, simultaneously measuring a current that flows between the source and the drain in each of the selected memory cells.

12. The method of claim 9, wherein the applying voltages to the source and the drain of the transistor in the one or more selected memory cells includes applying a first voltage to the source of the transistor in each selected memory cells and a second voltage to the drain of the transistor in each selected memory cells, the second voltage being greater than the first voltage.

13. The method of claim 9, wherein the applying inhibit voltages to the source and the drain of the transistor in each non-selected memory cell includes applying a third voltage to the source in each non-selected memory cell and a fourth voltage to the drain in each non-selected memory cell, the difference between the third voltage and the fourth voltage being less than a threshold voltage of the transistor in each non-selected memory cell.

14. The method of claim 9, wherein the applying inhibit voltages to the source and the drain of the transistor in each non-selected memory cell includes applying a third voltage to the source of the non-selected memory cell and a fourth voltage to the drain of the non-selected memory cell, the third voltage being substantially equal to the fourth voltage.

15. A non-volatile memory device comprising:
a plurality of memory cells, each said memory cell including a transistor with a source region, a drain region, a channel region between the source region and the drain region, and a gate electrode provided over the channel region;
a plurality of bit lines, each said bit line extending along a first direction, each said drain region being connected to one of the plurality of bit lines;
a plurality of source lines, each said source line extending along a second direction, each said source region being connected to one of the plurality of source lines; and
a common gate line, each said gate electrode being connected to the common gate line.

16. The non-volatile memory device of claim 15, wherein each source line and each bit line are configured such that a voltage can be applied thereto independent from other source lines and other bit lines, respectively.

17. The non-volatile memory device of claim 15, wherein each said memory cell includes a charge storage region arranged between the gate electrode and the channel region.

18. The non-volatile memory device of claim 15, wherein the gate electrodes of the transistors are formed using a self-alignment process.

19. The non-volatile memory device of claim 15, wherein each said memory cell is a phase change memory cell.

20. The non-volatile memory device of claim 15, wherein the plurality of bit lines, the plurality of source lines, and the common gate line are arranged such that memory states of memory cells with source regions connected by one of the source lines are simultaneously read out by measuring current on the respective bit lines during a read operation.
